(19) United States
(12) Patent Application Publication
(10) Pub. No.: US 2009/0140318 A1
(43) Pub. Date: Jun. 4, 2009

(54) NONVOLATILE MEMORIES WITH HIGHER CONDUCTION-BAND EDGE ADJACENT TO CHARGE-TRAPPING DIELECTRIC

(76) Inventor: Zhong Dong, Fremont, CA (US)

Correspondence Address: Haynes and Boone, LLP;IP Section, 2323 Victory Avenue, SUITE 700, Dallas, TX, 75219, US

(21) Appl. No.: 11/949,596

(22) Filed: Dec. 3, 2007

(51) Int. Cl. H01L 29/68

(52) U.S. Cl. 257/321; 257/E29.17

(57) ABSTRACT

In a nonvolatile memory, the tunnel dielectric (150) has a surface in physical contact with the charge trapping dielectric (160) and also has a surface in physical contact with a semiconductor region providing the active area (120, 130, 140). Under the vacuum level, the bottom edge of the conduction band of the tunnel dielectric (150) is higher at the surface contacting the charge-trapping dielectric (160) than at the surface contacting the active area.

### BACKGROUND OF THE INVENTION

The present invention relates to nonvolatile memories with charge-trapping dielectric which stores electric charge to define the memory state.

The charge-trapping dielectric can be silicon nitride. The charge-trapping dielectric is separated from the memory's channel region by tunnel dielectric, and from the control gate by blocking dielectric (or vice versa, i.e. the tunnel dielectric may be adjacent to the control gate and the blocking dielectric adjacent to the channel region). The tunnel and blocking dielectrics can be made of silicon dioxide or some other materials having a higher conduction band than each of silicon nitride, the silicon of the channel region, and the material of the control gate. The tunnel and blocking dielectrics hence provide energy barriers for electrons in the conduction band. These energy barriers reduce the leakage current and therefore improve data retention. Disadvantageously, these barriers increase voltages and times required to program or erase the memory.

### SUMMARY

This section summarizes some features of the invention. Other features are described in the subsequent sections. The invention is defined by the appended claims, which are incorporated into this section by reference.

In some embodiments, the tunnel and/or blocking dielectric has a non-uniform conduction-band profile under the vacuum level. “Under the vacuum level” means herein that the energy levels are shown as if each layer were in vacuum by itself, separated from other materials. The bottom edge of the conduction band of the tunnel and/or blocking dielectric is higher adjacent to the charge-trapping dielectric. It is believed that such a structure may improve the data retention with a smaller increase in the programming and erasure times and voltages than a uniform profile of the conduction band.

The invention is not limited to the features and advantages described above. Other features are described below. The invention is defined by the appended claims.

### BRIEF DESCRIPTION OF THE DRAWINGS

FIG. 1 illustrates a vertical cross section illustration of a memory cell according to some embodiments of the present invention.

FIG. 2 is a block diagram of a voltage generator for use in some embodiments of the present invention.

FIGS. 3 and 4 are energy band diagrams under the vacuum level for some embodiments of the present invention.

### DESCRIPTION OF SOME EMBODIMENTS

The embodiments described in this section illustrate but do not limit the invention. The invention is defined by the appended claims.

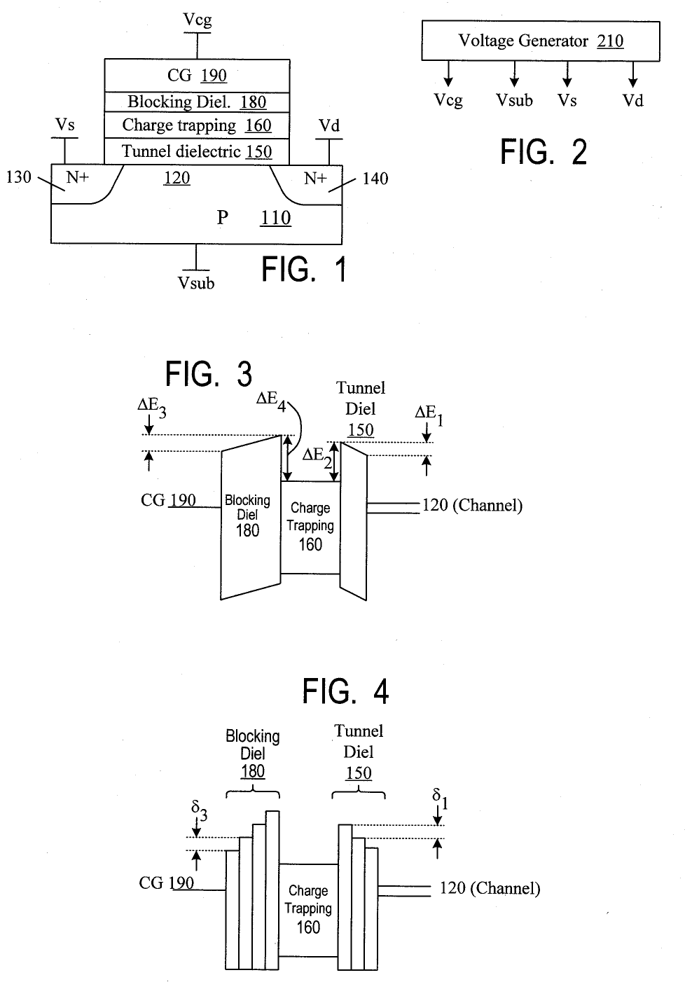

FIG. 1 illustrates a vertical cross section of a nonvolatile memory cell. The cell's active area is a semiconductor region which is part of a semiconductor substrate 110. Substrate 110 can be monocrystalline silicon or some other suitable material. The active area includes a P-type channel region 120 and N-type source/drain regions 130, 140 (the P and N conductivity types can be reversed). For ease of reference, the region 130 will be called “source”, and the region 140 will be called “drain”. In fact, in some embodiments each of regions 130, 140 can act as a source or a drain in the same cell in different modes of operation.

Tunnel dielectric 150 is formed on substrate 110 in physical contact with channel region 120 and/or all or part of source/drain regions 130, 140. In some embodiments, tunnel dielectric 150 is a layer of silicon dioxide, or silicon nitride, or titanium oxide, or a combination of these materials, or some other suitable material. See e.g. the aforementioned U.S. patent application published as 2006/0261401 A1 on Nov. 23, 2006, filed by Bhattacharyya, incorporated herein by reference. Charge-trapping dielectric 160 is formed on dielectric 150. In some embodiments, dielectric 160 is a layer of silicon nitride (possibly silicon-rich silicon nitride) which is 4 nm to 14 nm thick. This thickness is not limiting. Other possible materials include silicon oxynitride, tantalum nitride, tantalum oxide, aluminum nitride, and possibly others.

Blocking dielectric 180 is formed directly on charge-trapping dielectric 160. In some embodiments, blocking dielectric 180 is silicon dioxide, silicon nitride, aluminum oxide, or some other dielectric.

Control gate 190 is a conductive layer (e.g. metal, possibly tantalum) formed directly on blocking dielectric 180.

Voltage generator 210 (FIG. 2) can be a conventional circuit which generates a voltage Vcg for control gate 210, a voltage Vsub for substrate 110, a voltage Vs for source region 130, and a voltage Vd for drain region 140. These voltages can be generated in response to commands such as “program”, “erase”, “read”. Voltage generator 210 can be part of the same integrated circuit as the memory cell. Alternatively, all or part of the voltage generator can be external to the integrated circuit.

FIG. 3 is an energy band diagram for the memory cell, with each of layers 190, 180, 160, 150, 120 being pictured under the vacuum level (i.e. as if separated from the other layers). The band-gap energy range of channel region 120 (i.e. the energies between the valence band and the conduction band) is entirely within the band-gap energy range of tunnel dielectric 150. The band-gap energy range of dielectric 150 contains the band-gap energy range of charge-trapping dielectric 160, which is within the band-gap energy range of blocking dielectric 180, which contains the Fermi level of control gate 190.

The conduction band of tunnel dielectric 150 is higher than the conduction bands of channel region 120 and charge-trapping dielectric 160. The conduction band of blocking dielectric 180 is higher than the conduction bands of control gate 190 and charge-trapping dielectric 160.

The conduction band of tunnel dielectric 150 has a non-uniform profile. The bottom edge of the conduction band is lower adjacent to substrate 110 (channel 120) than adjacent to charge-trapping dielectric 160. The bottom edge increases on the way towards charge-trapping dielectric 160, possibly in step-wise fashion (FIG. 4). The total increase ΔE₁ is 0.1 eV to 2.0 eV in some embodiments, and other values are possible. This profile results in a higher energy barrier ΔE₂ for emission of conduction band electrons from charge-trapping dielectric 160 to substrate 110, thus improving the data retention time. Also, the lower bottom edge adjacent to channel 120 serves to reduce the programming and erasure times and voltages. In some embodiments, the memory is programmed and erased by direct tunneling of conduction-band electrons or holes through dielectric 150.

In some embodiments, the non-uniform profile of the conduction band of tunnel dielectric 150 is achieved by forming tunnel dielectric 150 as a combination of different layers (three layers in the example of FIG. 4) with conduction bands having successively higher bottom edges. For example, a combination of silicon dioxide layers can be used, with each successive layer (i.e. each layer further away from substrate 110) having a higher silicon content than the previous layer. See U.S. Pat. No. 4,104,675 issued Aug. 1, 1978 to Di Maria et al., incorporated herein by reference. Other combinations of layers include a sequence of layers of HfO₂, Al₂O₃, SiO₂ (starting at substrate 110), or a sequence of HfO₂, SiON, SiO₂, which are described in the aforementioned U.S. patent publication 2006/0261401 A1. Other combinations of layers are also possible. In some embodiments, the offset δ₁ of the bottom edge of the conduction band of each subsequent layer in the sequence is at least 0.01 eV relative to the preceding layer.

In some embodiments, blocking dielectric 180 also has a non-uniform profile of its bottom edge of the conduction band. The bottom edge increases on the way from control gate 190 to charge-trapping dielectric 160. The total increase ΔE₃ is 0.1 eV to 3.0 eV in some embodiments, and other values are possible. This profile results in a higher barrier ΔE₄ for emission of conduction band electrons from charge-trapping dielectric 160 to control gate 190, thus improving the data retention time. Adjacent to control gate 190, the blocking dielectric may include a layer with a higher dielectric constant than adjacent to charge-trapping dielectric 160. The layer with a higher dielectric constant advantageously increases the coupling ratio between control gate 190 and charge-trapping dielectric 160. Layers with higher dielectric constants may have a lower bottom edge value of the conduction band.

In some embodiments, the non-uniform profile of the conduction band of blocking dielectric 180 is achieved by forming blocking dielectric 180 as a sequence of different layers (four layers in the example of FIG. 4) with successively lower bottom edges of conduction bands. See the aforementioned U.S. Pat. No. 4,104,675 and U.S. patent publication 2006/0261401 A1 for suitable materials. In some embodiments, the offset δ₃ of the bottom edge of the conduction band for each subsequent layer in the sequence of layers is at least 0.01 eV.

The memory cell can be operated in the same manner as conventional charge-trapping cells. For example, the memory cell can be programmed by providing the voltage Vcg of 10V to 18V on control gate 190 and providing the ground voltage Vsub on substrate 110. The source/drain regions 130, 140 float. As a result, charge-trapping dielectric 160 becomes negatively charged. It is believed that the negative charge (e.g. conduction and/or valence band electrons) is transferred from channel region 120 through tunnel dielectric 150 into the conduction band of dielectric 160 via direct or Fowler-Nordheim (FN) tunneling. However, the invention does not depend on any particular theory of operation except as defined by the claims.

In some embodiments, the memory is erased by supplying a voltage Vsub of 8V to 18V to substrate 110 while holding the control gate at ground. The source/drain regions 130, 140 float. The negative charge in charge-trapping dielectric 160 is erased, perhaps by direct or FN tunneling of conduction-band and/or valence-band electrons into channel 120.

The memory cell can be read by providing a voltage difference between the source/drain regions 130, 140 and driving the control gate 190 to a voltage level which is between threshold voltages of the memory cell in the programmed and the erased states.

The memory cell can be fabricated using known techniques. In some embodiments, a P well is provided in substrate 110, then dielectric 150 is formed on the P well, then charge-trapping dielectric 160 is formed, then blocking dielectric 180 is formed, then control gate layer 190 is formed. Possibly additional layers are formed over the layer 190. The layers are patterned at suitable stages of fabrication. Source/drain regions 130, 140 are doped as needed.

The invention is not limited to the embodiments described above. In some embodiments, the memory cell is programmed and/or erased by charge transfer from or to source region 130 and/or drain region 140, and/or by hot electron injection. The memory cell can be a multi-state cell, possibly with multiple regions of charge-trapping dielectric with each region capable of storing charge independently of the other region or regions. The memory cell can be part of a memory array. Many memory array and memory cell architectures commonly used for charge-trapping memories can also be used in conjunction with the present invention. In particular, non-planar memory cells, split-gate memory cells, NAND, AND, NOR and other arrays can be used. Charge-trapping dielectric 160 can be made of materials other than silicon nitride, and can be embedded with nanocrystals and/or implemented as a combination of layers with different energy bands. The invention is not limited to planar structures. For example, the charge-trapping dielectric and the tunnel dielectric may be formed as conformal layers over sidewalls of a protrusion (a fin) on substrate 110 or over sidewalls of a trench in substrate 110.

Some embodiments of the invention include a nonvolatile memory comprising: a semiconductor region providing the memory's active area (e.g. 120 and/or 130 and/or 140); a charge-trapping dielectric for storing electrical charge to define a state of the memory; a conductive gate for controlling the nonvolatile memory; and a tunnel dielectric separating the charge-trapping dielectric from the semiconductor region, the tunnel dielectric having a first surface in physical contact with the charge-trapping dielectric and having a second surface in physical contact with the semiconductor region. For example, in FIG. 1, the first surface is the top surface of dielectric 150, and the second surface is the bottom surface. In some embodiments, under the vacuum level, a bottom edge of a conduction energy band of the tunnel dielectric is higher at the first surface (in contact with the charge-trapping dielectric) than at the second surface.

Some embodiments include a blocking dielectric blocking dielectric separating the charge-trapping dielectric from either the conductive gate, the blocking dielectric having a third surface in physical contact with the charge-trapping dielectric and having a fourth surface in physical contact with the conductive gate. For example, in FIG. 1, the third surface is the bottom surface of dielectric 180, and the fourth surface is the top surface of dielectric 180. In some embodiments, under the vacuum level, a bottom edge of a conduction energy band of the blocking dielectric is higher at the third surface (at the surface in physical contact with the charge-trapping dielectric) than at the fourth surface.

Some embodiments include a nonvolatile memory comprising: a semiconductor region providing the memory's active area (e.g. 120 and/or 130 and/or 140); a tunnel dielectric in physical contact with the semiconductor region; a charge-trapping dielectric in physical contact with the tunnel dielectric, the tunnel dielectric separating the charge-trapping dielectric from the semiconductor region; and a conductive gate for controlling the nonvolatile memory; wherein the tunnel dielectric comprises a sequence of layers, with a first layer of the sequence being adjacent to the active area and the last layer of the sequence being adjacent to the charge-trapping dielectric, wherein each subsequent layer in the sequence has a positive conduction-band offset (e.g. offset δ₁ in FIG. 4) relative to the immediately preceding layer in the sequence

Some embodiments include a nonvolatile memory comprising: a semiconductor region providing the memory's active area; a charge-trapping dielectric for storing electrical charge to define a state of the memory; a conductive gate for controlling the nonvolatile memory; a first dielectric (e.g. 150 or 180) separating the charge-trapping dielectric from either the semiconductor region or the conductive gate, the first dielectric having a first surface in physical contact with the charge-trapping dielectric and having a second surface in physical contact with either the semiconductor region or the conductive gate; and a second dielectric (e.g. 180 or 150) on an opposite side of the charge-trapping dielectric from the first dielectric, the second dielectric separating the charge-trapping dielectric from either the conductive gate or the semiconductor region, the second dielectric having a third surface in physical contact with the charge-trapping dielectric and having a fourth surface in physical contact with either the conductive gate or the semiconductor region; wherein under the vacuum level, a bottom edge of a conduction energy band of the first dielectric is higher at the first surface than at the second surface.

In some embodiments, the first dielectric comprises a sequence of layers, with a first layer of the sequence being at the second surface and the last layer of the sequence being adjacent to the charge-trapping dielectric, wherein each subsequent layer in the sequence has a positive conduction-band offset relative to the immediately preceding layer in the sequence.

Other embodiments are within the scope of the invention, as defined by the appended claims. Any reference numerals in the claims are provided to elucidate support for the claims in the drawings but not to limit the invention or its possible interpretation in view of the drawings. The invention also includes methods for fabricating nonvolatile memory and methods of operating (e.g. reading, programming, erasing) nonvolatile memory.

1. A nonvolatile memory comprising:
a semiconductor region providing the memory's active area;
a charge-trapping dielectric for storing electrical charge to define a state of the memory;
a conductive gate for controlling the nonvolatile memory; and
a tunnel dielectric separating the charge-trapping dielectric from the semiconductor region, the tunnel dielectric having a first surface in physical contact with the charge-trapping dielectric and having a second surface in physical contact with the semiconductor region;
wherein under the vacuum level, a bottom edge of a conduction energy band of the tunnel dielectric is higher at the first surface than at the second surface.

2. The nonvolatile memory of claim 1 further comprising a blocking dielectric separating the charge-trapping dielectric from the conductive gate, the blocking dielectric having a third surface in physical contact with the charge-trapping dielectric and having a fourth surface in physical contact with the conductive gate;
wherein under the vacuum level, a bottom edge of a conduction energy band of the blocking dielectric is higher at the third surface than at the fourth surface.

3. A nonvolatile memory comprising:
a semiconductor region providing the memory's active area;
a tunnel dielectric in physical contact with the semiconductor region;
a charge-trapping dielectric in physical contact with the tunnel dielectric, the tunnel dielectric separating the charge-trapping dielectric from the semiconductor region; and
a conductive gate for controlling the nonvolatile memory;
wherein the tunnel dielectric comprises a sequence of layers, with a first layer of the sequence being adjacent to the active area and the last layer of the sequence being adjacent to the charge-trapping dielectric, wherein each subsequent layer in the sequence has a positive conduction-band offset relative to the immediately preceding layer in the sequence.

4. The nonvolatile memory of claim 3 further comprising a blocking dielectric separating the charge-trapping region from the conductive gate.

5. A method for manufacturing the nonvolatile memory of claim 1, the method comprising forming the tunnel dielectric, the charge-trapping dielectric, and the conductive gate.

6. A method for operating the nonvolatile memory of claim 1, the method comprising providing a voltage between the conductive gate and the semiconductor region to cause charge transfer to or from the charge-trapping dielectric via the tunnel dielectric.

7. A method for operating the nonvolatile memory of claim 1, wherein the active area comprises first and second source/drain regions, the method comprising providing a voltage on the conductive gate and generating a signal responsive to a current between the source/drain regions.

8. A nonvolatile memory comprising:
a semiconductor region providing the memory's active area;
a charge-trapping dielectric for storing electrical charge to define a state of the memory;
a conductive gate for controlling the nonvolatile memory;
a first dielectric (150 or 180) separating the charge-trapping dielectric from either the semiconductor region or the conductive gate, the first dielectric having a first surface in physical contact with the charge-trapping dielectric and having a second surface in physical contact with either the semiconductor region or the conductive gate; and
a second dielectric (180 or 150) on an opposite side of the charge-trapping dielectric from the first dielectric, the second dielectric separating the charge-trapping dielectric from either the conductive gate or the semiconductor region, the second dielectric having a third surface in physical contact with the charge-trapping dielectric and having a fourth surface in physical contact with either the conductive gate or the semiconductor region;
wherein under the vacuum level, a bottom edge of a conduction energy band of the first dielectric is higher at the first surface than at the second surface.

9. The nonvolatile memory of claim 8 wherein the first dielectric is the blocking dielectric.

10. The nonvolatile memory of claim 8, wherein the first dielectric comprises a sequence of layers, with a first layer of the sequence being at the second surface and the last layer of the sequence being adjacent to the charge-trapping dielectric, wherein each subsequent layer in the sequence has a positive conduction-band offset relative to the immediately preceding layer in the sequence.

11. The nonvolatile memory of claim 10 wherein the first dielectric is a charge-trapping dielectric.

12. A method for manufacturing the nonvolatile memory of claim 8, the method comprising forming the tunnel dielectric, the charge-trapping dielectric, the blocking dielectric, and the conductive gate.

13. A method for operating the nonvolatile memory of claim 8, the method comprising providing a voltage between the conductive gate and the semiconductor region to cause charge transfer to or from the charge-trapping dielectric via the tunnel dielectric.

14. A method for operating the nonvolatile memory of claim 8, wherein the active area comprises first and second source/drain regions, the method comprising providing a voltage on the conductive gate and generating a signal responsive to a current between the source/drain regions.
